(19) United States
(12) Patent Application Publication
(10) Pub. No.: US 2022/0018636 A1
(43) Pub. Date: Jan. 20, 2022

(54) SHOOTING TARGET AND TRAINING APPARATUS

(71) Applicant: LIBI YEDAYA, YAKIR (IL)

(72) Inventor: LIBI YEDAYA, YAKIR (IL)

(21) Appl. No.: 17/373,835

(22) Filed: Jul. 13, 2021

Related U.S. Application Data
(60) Provisional application No. 63/051,905, filed on Jul. 15, 2020.

(51) Int. Cl. F41J 5/04; F41J 1/00

(52) U.S. Cl. CPC F41J 5/04; F41J 1/00

(57) ABSTRACT

A shooting target, including an air blower, a fabric envelope assembled on the air blower, for being inflatable thereby, and an electric current meter, for measuring electric current flowing through the air blower, thereby allowing indicating a bullet shot on the fabric envelope while being inflated, upon determining a change in the measured electric current.

### CROSS-REFERENCE TO RELATED APPLICATIONS

This application claims the benefit of priority U.S. Provisional Application No. 63/051,905, filed Jul. 15, 2020, the disclosure of which is incorporated herein by reference.

### TECHNICAL FIELD

The invention relates to the field of shooting training.

### BACKGROUND

Shooting targets are disadvantaged in that they provide a poor indication of the result of shooting performed thereon, being a small hole only.

There is a long-felt need to provide a solution to the above-mentioned problem and other problems of the prior art.

### SUMMARY

The invention, in embodiments thereof, provides a shooting target, including an air blower, a fabric envelope, and an electric current meter.

### BRIEF DESCRIPTION OF THE DRAWINGS

Embodiments, features, and aspects of the invention are described herein in conjunction with the following drawings:

FIG. 1 is a front view of a shooting apparatus according to one embodiment of the invention.

FIG. 2 is a front view of one of the shooting targets of FIG. 1.

FIG. 3 is a front view of the shooting target of FIG. 2 upon being shot.

FIG. 4 is a front view of the shooting target of FIG. 3 upon being controlled by the central control after the shooting.

FIG. 5 is a front view of the shooting target of FIG. 3 upon being shot again.

The drawings are not necessarily drawn to scale.

### DETAILED DESCRIPTION

The invention will be understood from the following detailed description of embodiments of the invention, which are meant to be descriptive and not limiting. For the sake of brevity, some well-known features are not described in detail.

The reference numbers have been used to point out elements in the embodiments described and illustrated herein, in order to facilitate the understanding of the invention. They are meant to be merely illustrative, and not limiting. Also, the foregoing embodiments of the invention have been described and illustrated in conjunction with systems and methods thereof, which are meant to be merely illustrative, and not limiting.

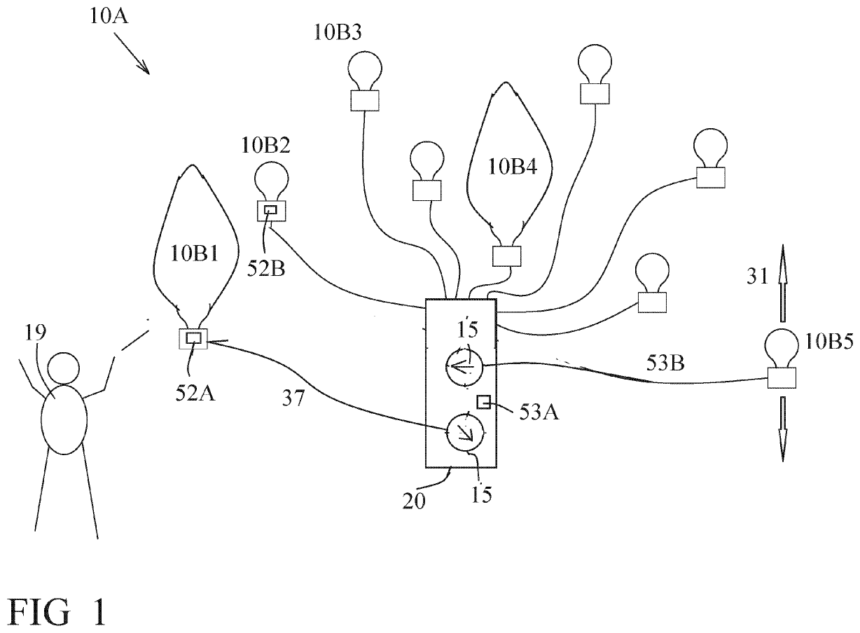

FIG. 1 is a front view of a shooting apparatus according to one embodiment of the invention.

A shooting apparatus 10A according to one embodiment includes multiple shooting targets 10B1, 10B2, etc., being controlled by a central control 20 through wire or wireless communication 37. According to another embodiment, each shoortin target 10B1 independently controls itself by its controller.

Central control 20 controls air blower 52A of shooting target 10B1 independently from air blower 52B of shooting target 10B2.

According to another embodiment, central control 20 includes a central air blower or compressor 53A, for inflating through air pipes 53B extending between central air blower 53A to each shooting target.

In the example of FIG. 1, central control 20 currently prepares shooting targets 10B1 and 10B4 only, to be currently available for shooting by filling air thereto only.

The trainer which may be human or robotic, may move (31) shooting target 10B5 and others.

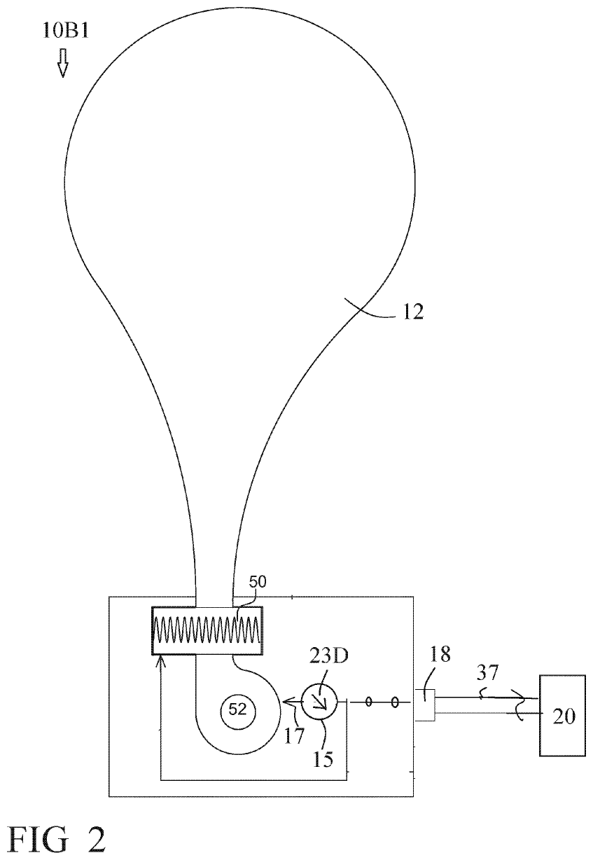

FIG. 2 is a front view of one of the shooting targets of FIG. 1.

Shooting target 10B1 according to one embodiment includes an air blower 52A, a fabric envelope 12 assembled on air blower 52A, for being filled with air, thus inflating fabric envelope 12 to make it available for shooting thereon, an electric current meter 15, for measuring the electric current 17 flowing for operating air blower 52A, and a controller 18 communicating with central control 20, for operating air blower 52A.

Electric current meters 15 may be disposed within central control 20, as shown in FIG. 1.

Shooting target 10B1 may further include a heating element or a chemical substance releasing element 50 for heating the air filled within fabric envelope 12.

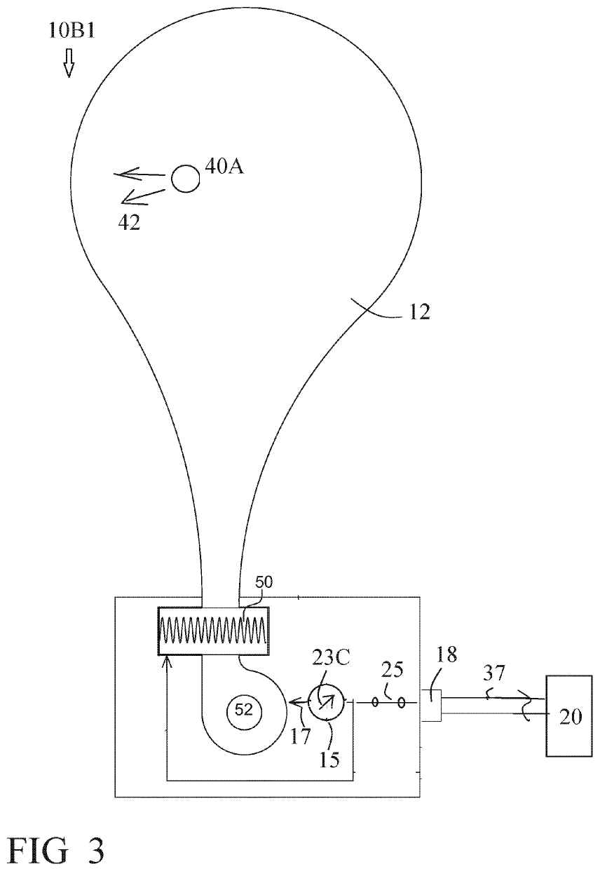

FIG. 3 is a front view of the shooting target of FIG. 2 upon being shot.

In case shooting target 10B1 is shot by a bullet, a small air portion 42 only flown by air blower 52A exits fabric envelope 12 through a punch 40A at a time, thus the inflating of air blower 52A is larger than the release of air through hole 40A, thus fabric envelope 12 is yet inflated.

The existing air releases air resistance, thus air blower 52A works easier for continuing filling fabric envelope 12 with air, thus electric-current meter 15 measures electric current 17 of extent 23C being smaller than extent 23D of FIG. 2.

The decrease of electric current 17 from 23D to 23C is an indication of successful shooting. Central control 20 receives the information of the decrease of electric current 17.

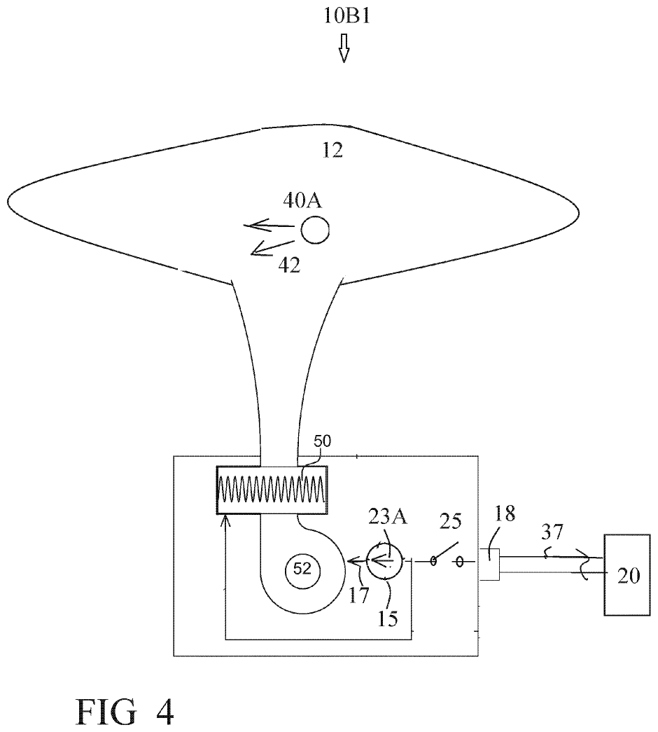

FIG. 4 is a front view of the shooting target of FIG. 3 upon being controlled by the central control after the shooting.

Central control 20 upon receiving the information may then cut an on/off switch 25 for turning off air blower 52A, thus electric current 17 is zero, shown by extent 23A. The rest of the air will exit through hole 40A thus fabric envelope 12 diminishes.

At a later stage, central control 20 may close switch 25 to operate again air blower 52A for inflating fabric envelope 12 of target 10B1 again. The electric current 17 for filling fabric envelope 12 having hole 40A is again of extent 23C of FIG. 3, being smaller than current 23D without hole 40A of FIG. 2.

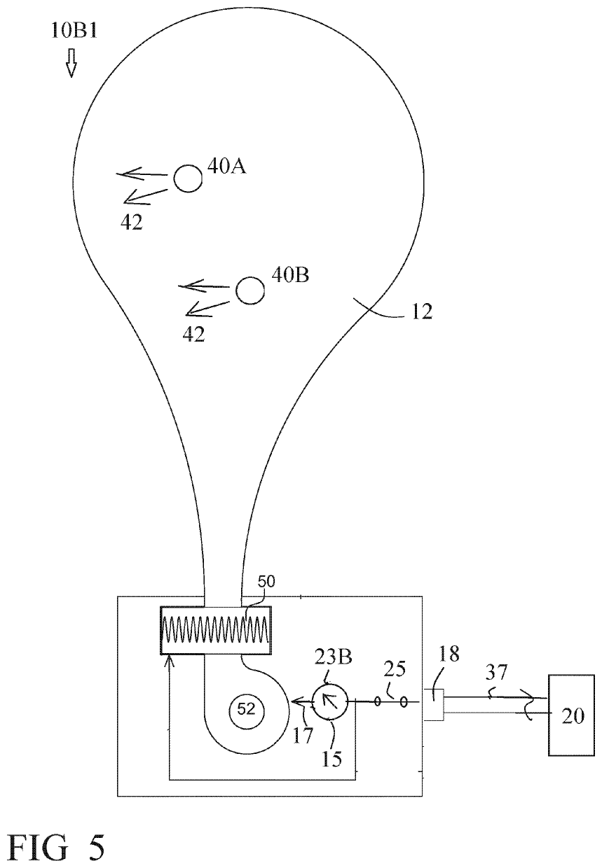

FIG. 5 is a front view of the shooting target of FIG. 3 upon being shot again.

In case shooting target 10B1 is shot again by a second bullet, air 42 exits fabric envelope 12 through hole 40A and a new hole 40B. The inflating of air blower 52A is yet larger than the release of air through hole 40A, thus fabric envelope 12 is yet inflated.

With additional hole 40B, electric current meter 15 measures electric current 17 of extent 23B being smaller than extent 23C of FIG. 3.

The decrease of electric current 17 from 23C to 23B is an indication of an additional successful shooting.

Central control 20 upon receiving the information may then cut an on/off switch 25 for turning off air blower 52A, thus electric current 17 is zero, shown by extent 23A. The rest of the air will exit through hole 40A thus fabric envelope 12 diminishes.

At a later stage, central control 20 may close switch 25 to operate again air blower 52A for inflating fabric envelope 12 of target 10B1 again. The electric current 17 for filling fabric envelope 12 having holes 40A and 40B is again of extent 23B of FIG. 5.

Thus, in one aspect, the invention is directed to a shooting target (10B1), including an air blower (52A), a fabric envelope (12) assembled on the air blower (52A), for being inflatable thereby, an electric current meter (15), for measuring electric current (17) flowing through the air blower (52A), thereby allowing indicating a bullet shot on the fabric envelope (12) while being inflated, upon determining a change in the measured electric current (17).

The shooting target (10B1) may further include a controller (18), for controlling the air blower (52A), for inflating and ceasing the inflating of the fabric envelope (12) as a function of the indication of the bullet, shot on the fabric envelope (12).

The shooting target (10B1) may further include a heating accessory (50), for heating the air blown by the air blower (52A), thereby the inflation of the fabric envelope (12) is of heated air, thereby the fabric envelope (12) is detectable by a thermal detector.

In another aspect, the invention is directed to a shooting training apparatus (10A), including multiple shooting targets (10B1,10B2), each including a separate fabric envelope (12) being inflatable and punchable by bullets, and a central control (20), for remotely inflating targets selected from the shooting targets (10B1,10B2) independently from one another, where the shooting targets (10B1,10B2) are mobile and movable from one another thereby being each shootable at a different location, and where the inflation is available at the punchability, thereby allowing the central control (20) to establish targets of the shooting targets (10B1,10B2) independent of one another by inflating the fabric envelopes (12) thereof, and to cancel the establishing by ceasing the inflation.

The shooting training apparatus (10A) may further include a detector (15) for each of the shooting targets (10B1,10B2), for detecting presence of punches induced by the bullets, and for reporting the presence to the central control (20).

The detector (15) may constitute an electric-current meter.

In the figures and/or description herein, the following reference numerals (Reference Signs List) have been mentioned:

numeral 10A denotes the shooting training apparatus according to one embodiment of the invention;

10B1,10B2,10B3,10B4,10B5: shooting target;

12: inflatable fabric envelope;

15: electric-current meter or electric-power meter;

17: electric current;

18: controller of shooting target;

19: trainee shooting bullets;

20: central control;

23A,23B,23C,23D: extents of electric currents from zero to large;

25: electrical switch controlled by controller 18;

31: movement of the shooting target;

37: communication;

40A,40B: punches;

42: air exiting punch 40A;

50: heating accessory, such as heating element or a chemical substance releasing element;

52A,52B: air blowers each disposed within one shooting target;

53A: air blower or compressor;

53B: air pipe.

The foregoing description and illustrations of the embodiments of the invention have been presented for the purpose of illustration, and are not intended to be exhaustive or to limit the invention to the above description in any form.

Any term that has been defined above and used in the claims, should be interpreted according to this definition.

The reference numbers in the claims are not a part of the claims, but rather used for facilitating the reading thereof. These reference numbers should not be interpreted as limiting the claims in any form.

What is claimed is:

1. A shooting target, comprising:
an air blower;
a fabric envelope assembled on said air blower, for being inflatable thereby; and
an electric current meter, for measuring electric current flowing through said air blower,
thereby allowing indicating a bullet shot on said fabric envelope while being inflated, upon determining a change in said measured electric current.

2. The shooting target according to claim 1, further comprising:
a controller, for controlling said air blower, for inflating and ceasing the inflating of said fabric envelope as a function of said indication of the bullet, shot on said fabric envelope.

3. The shooting target according to claim 1, further comprising:
a heating accessory, for heating the air blown by said air blower,
thereby said inflation of said fabric envelope is of heated air, thereby said fabric envelope is detectable by a thermal detector.

4. A shooting training apparatus, comprising:
a plurality of shooting targets, each comprising a separate fabric envelope being inflatable and punchable by bullets; and
a central control, for remotely inflating targets selected from said shooting targets independently from one another,
wherein said shooting targets are mobile and movable from one another thereby being each shootable at a different location, and
wherein said inflation is available at said punchability,
thereby allowing said central control to establish targets of said shooting targets independent of one another by inflating said fabric envelopes thereof, and to cancel said establishing by ceasing said inflation.

5. The shooting training apparatus according to claim 4, further comprising:
a detector for each of said shooting targets, for detecting presence of punches induced by the bullets, and for reporting said presence to said central control.

6. The shooting training apparatus according to claim 5, wherein said detector comprises an electric current meter.
